(19) United States
(12) Patent Application Publication
(10) Pub. No.: US 2011/0169081 A1
(43) Pub. Date: Jul. 14, 2011

(54) SEMICONDUCTOR DEVICE AND METHOD FOR MANUFACTURING THE SAME

(75) Inventors: Hironori Ishikawa, Tokyo (JP); Shinya Sato, Hyogo-ken (JP); Hiroyuki Sugaya, Hyogo-ken (JP); Tomoyuki Sakuma, Hyogo-ken (JP)

(73) Assignee: Kabushiki Kaisha Toshiba, Tokyo (JP)

(21) Appl. No.: 12/986,821

(22) Filed: Jan. 7, 2011

(30) Foreign Application Priority Data
Jan. 8, 2010 (JP) 2010-003094

(51) Int. Cl. H01L 29/68; H01L 21/20

(52) U.S. Cl. 257/341; 438/478; 257/E29.169; 257/E21.09

(57) ABSTRACT

According to one embodiment, a semiconductor device includes a first semiconductor layer of a first conductivity type and a second semiconductor layer of a second conductivity type. The first semiconductor layer is formed with a trench. The second semiconductor layer is buried in the trench, and includes a hollow portion. A length of the hollow portion along depth direction of the trench is 5 μm or less or 15 μm or more.

### CROSS-REFERENCE TO RELATED APPLICATIONS

This application is based upon and claims the benefit of priority from the prior Japanese Patent Application No. 2010-003094, filed on Jan. 8, 2010; the entire contents of which are incorporated herein by reference.

### FIELD

Embodiments described herein relate generally to a semiconductor device and a method for manufacturing the same.

### BACKGROUND

As a power control semiconductor device achieving compatibility between high breakdown voltage and low on-resistance, a vertical MOSFET (metal oxide semiconductor field effect transistor) having a super junction structure (hereinafter also referred to as “SJ structure”) is known. The SJ structure includes p-type semiconductor pillars buried in an n-type semiconductor layer so that n-type portions and p-type portions are alternately arranged. In the SJ structure, by equalizing the amount of impurity contained in the n-type portion with that contained in the p-type portion, a non-doped layer is artificially produced to sustain a high breakdown voltage. Furthermore, low on-resistance can be achieved by passing a current through the n-type portion having high impurity concentration.

One of the methods for forming a MOSFET having such a SJ structure is as follows. An n-type semiconductor layer is grown on an n⁺-type semiconductor substrate by epitaxial growth. A plurality of trenches are formed in this semiconductor layer. A p-type semiconductor material is epitaxially grown in the trench to form a p-type semiconductor pillar (see, e.g., JP-A 2007-173734(Kokai)).

However, when the p-type semiconductor material is epitaxially grown in the trench, a hollow portion (void) tends to be formed in the grown film. This hollow portion may induce crystal defects in the grown film in the trench. Such crystal defects impact on the characteristics of the semiconductor device such as the vertical MOSFET, particularly on the reliability such as leak voltage.

### BRIEF DESCRIPTION OF THE DRAWINGS

FIG. 1 is a schematic sectional view describing an example of a semiconductor device;

FIG. 2 illustrates the relationship between a length of the hollow portion and a density of crystal defects;

FIGS. 3A and 3B are plan views illustrating a method for manufacturing a semiconductor device;

FIG. 4 illustrates flow of raw material gas; and

FIGS. 5A and 5B are sectional views describing an example of a hollow portion.

### DETAILED DESCRIPTION

In general, according to one embodiment, a semiconductor device includes a first semiconductor layer of a first conductivity type and a second semiconductor layer of a second conductivity type. The first semiconductor layer is formed with a trench. The second semiconductor layer is buried in the trench, and includes a hollow portion. A length of the hollow portion along depth direction of the trench is 5 μm or less or 15 μm or more.

In general, according to another embodiment, a semiconductor device includes a first main electrode, a second main electrode, a first semiconductor layer of a first conductivity type, a first buried semiconductor layer of a second conductivity type, a second buried semiconductor layer of a second conductivity type, a third semiconductor layer of the second conductivity type, a fourth semiconductor layer of the first conductivity type, a fifth semiconductor layer of the second conductivity type, a sixth semiconductor layer of the first conductivity type and a control electrode. The first semiconductor layer of a first conductivity type is provided between the first main electrode and the second main electrode and has a first trench and a second trench. The second trench is aligned with the first trench formed at a predetermined pitch in a direction perpendicular to a direction from the first main electrode toward the second main electrode. The first buried semiconductor layer of a second conductivity type is buried in the first trench and includes a hollow portion in the first buried semiconductor layer. The second buried semiconductor layer of a second conductivity type is buried in the second trench and includes a hollow portion in the second buried semiconductor layer. The third semiconductor layer of the second conductivity type is provided between the first buried semiconductor layer and the second main electrode. The fourth semiconductor layer of the first conductivity type is selectively provided between a portion of the third semiconductor layer and the second main electrode. The fifth semiconductor layer of the second conductivity type is provided between the second buried semiconductor layer and the second main electrode. The sixth semiconductor layer of the first conductivity type is selectively provided between a portion of the fifth semiconductor layer and the second main electrode. The control electrode is provided between a portion between the first buried semiconductor layer and the second buried semiconductor layer and the second main electrode via an insulating film. The first main electrode is electrically connected to the first semiconductor layer. The second main electrode is connected to the fourth semiconductor layer and the sixth semiconductor layer. A length of the hollow portion along depth direction of the first and second trenches is 5 μm or less or 15 μm or more.

In general, according to another embodiment, a method for manufacturing a semiconductor device is disclosed. The method can include forming a trench in a first semiconductor layer of a first conductivity type and forming a second semiconductor layer by supplying a raw material gas to both end portions in longitudinal direction of the trench along one direction along the longitudinal direction and along two directions along width direction of the trench and supplying the raw material gas to an intermediate portion of the trench other than both the end portions along the two directions along the width direction to grow a semiconductor material of a second conductivity type in the trench. The second semiconductor layer includes a hollow portion inside the semiconductor material of the second conductivity type. A length of the hollow portion along depth direction of the trench is set to 5 μm or less or 15 μm or more.

Embodiments of the invention will now be described with reference to the drawings. The embodiments will be described with reference to an example in which the first conductivity type is n-type and the second conductivity type is p-type.

### First Embodiment

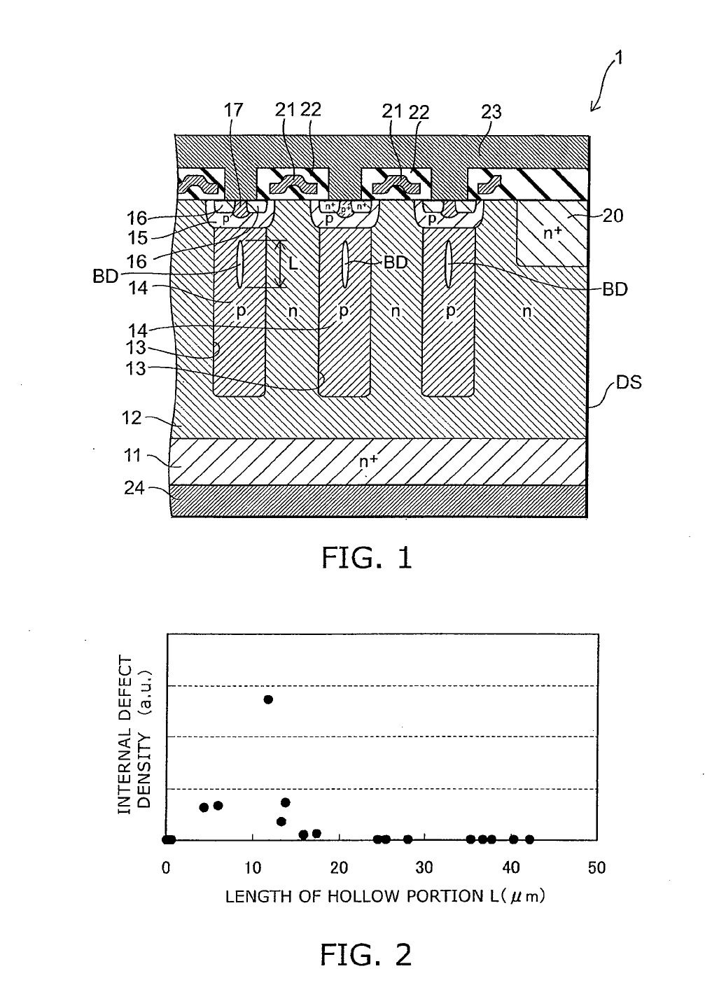

FIG. 1 is a schematic sectional view illustrating an example of a semiconductor device according to a first embodiment. The semiconductor device 1 according to this embodiment primarily includes an n-type silicon layer 12 as a first semiconductor layer of the first conductivity type with trenches 13 (first trench, second trench) formed therein, and a p-type silicon pillar 14 (first buried semiconductor layer, second buried semiconductor layer) as a second semiconductor layer of the second conductivity type buried in the trench 13 and including therein a hollow portion BD. In particular, the semiconductor device 1 of this embodiment is characterized in that the length L of this hollow portion BD along the depth direction of the trench 13 is 5 μm or less or 15 μm or more.

The semiconductor device 1 according to this embodiment shown in FIG. 1 is configured to include a vertical MOSFET having a Si structure as an example of the device structure. To realize this device structure, in the semiconductor device 1 according to this embodiment, an n⁺-type silicon substrate 11 made of n⁺-type single crystal silicon is provided as a semiconductor substrate. On the n⁺-type silicon substrate 11, an n-type silicon layer 12 made of n-type single crystal silicon is provided as a first semiconductor layer. Furthermore, in the n-type silicon layer 12, from the upper surface side of the n-type silicon layer 12, a plurality of trenches 13 extending in one direction parallel to this upper surface are formed. As viewed from above, the plurality of trenches 13 are formed parallel to each other.

The trench 13 is filled with p-type single crystal silicon. Thus, a p-type silicon pillar 14 is buried as a second semiconductor layer in the trench 13. In the n-type silicon layer 12, the p-type silicon pillar 14 and the portion of the n-type silicon layer 12 between the p-type silicon pillars 14 are alternately arranged to form a super junction structure (SJ structure). In the following, the depth direction (vertical direction in the figure) of the trench 13 filled with the p-type silicon pillar 14 is referred to as “trench direction”. The direction (horizontal direction in the figure) orthogonal to the trench direction, i.e., the arranging direction of the p-type silicon pillars 14, is referred to as “SJ direction”. Furthermore, the extending direction (the direction perpendicular to the page including the figure) of the p-type silicon pillar 14 is referred to as “pillar direction”.

Each trench 13 is formed from the upper surface of the n-type silicon layer 12 to a prescribed depth such as not to reach the n⁺-type silicon substrate 11. Furthermore, the trenches 13 are formed discontinuously throughout the semiconductor chip along the pillar direction. The p-type silicon pillar 14 is buried in each such trench 13. The p-type silicon pillar 14 is a layer formed by epitaxial growth in the trench 13.

The p-type silicon pillar 14 includes a hollow portion BD extending in the trench direction. The hollow portion BD is formed in accordance with the setting of the growth condition when the p-type silicon pillar 14 is formed by epitaxial growth. In this embodiment, the length L of the hollow portion BD along the trench direction is set to 5 μm or less or 15 μm or more. Such length setting is realized by the setting of the epitaxial growth condition for the p-type silicon pillar 14. By setting the length L of the hollow portion BD to the aforementioned size, the occurrence of crystal defects in the Si structure formed by epitaxial growth is suppressed.

A p-type base region 15 (third semiconductor layer, fifth semiconductor layer) extending in the pillar direction is formed immediately above the p-type silicon pillar 14 in the n-type silicon layer 12. In the upper portion of the p-type base region 15, a pair of n⁺-type source regions 16 (fourth semiconductor layer, sixth semiconductor layer) extending in the pillar direction is selectively formed so that the n⁺-type source regions 16 are spaced from each other. Furthermore, a p⁺-type contact region 17 is formed between the source regions 16 in the p-type base region 15.

In the terminal section of the semiconductor device 1, an n⁺-type diffusion region 20 is formed in the upper portion of the n-type silicon layer 12 and the p-type silicon pillar 14. The diffusion region 20 has higher impurity concentration than the n-type silicon layer 12. As viewed from above, the diffusion region 20 is shaped like a ring along the outer edge of the semiconductor device 1, i.e., along the outer edge of the n-type silicon layer 12.

Furthermore, a gate electrode 21 as a control electrode is provided on the n-type silicon layer 12, and a gate insulating film 22 is provided so as to enclose the gate electrode 21. The gate electrode 21 is formed from e.g. polysilicon. The gate insulating film 22 is formed from e.g. silicon oxide.

The gate electrode 21 is located immediately above the region between the adjacent source regions 16 formed in the adjacent p-type base regions 15. That is, the gate electrode 21 is provided immediately above one p-type base region 15, the n-type silicon layer 12, and the other p-type base region 15 arranged between the adjacent source regions 16. Hence, the gate electrode 21 is provided in a region including the immediately overlying region of the portion of the p-type base region 15 between the n-type silicon layer 12 and the source region 16. Furthermore, the gate electrode 21 is curved so as to be convex upward, for instance. Thus, the gate electrode 21 is relatively high at the center, i.e., at the position corresponding to the immediately overlying region of the n-type silicon layer 12, and is relatively low at both ends.

Moreover, a source electrode 23 as a second main electrode is provided between the gate electrodes 21 and on the gate electrode 21. The portion of the source electrode 23 between the gate electrodes 21 is connected to the source region 16 and the contact region 17. Furthermore, the gate electrode 21 is insulated from the n-type silicon layer 12 and the source electrode 23 by the gate insulating film 22. On the other hand, a drain electrode 24 as a first main electrode is provided on the lower surface of the n⁺-type silicon substrate 11 and connected to the n⁺-type silicon substrate 11. The source electrode 23 and the drain electrode 24 are formed from e.g. a metal. (Relationship between the hollow portion and the density of crystal defects)

FIG. 2 illustrates the relationship between the length of the hollow portion formed in the p-type silicon pillar (second semiconductor layer) and the density of crystal defects. The horizontal axis of FIG. 2 represents the length of the hollow portion (length L in FIG. 1). The vertical axis of FIG. 2 represents the density of crystal defects inside the SJ structure (n-type silicon layer 12 and p-type silicon pillar 14).

Here, in a trench formed to a depth of 50 μm in the n-type silicon layer, a p-type silicon pillar was formed by epitaxial growth. The length L of the hollow portion was adjusted by changing the ratio of SiH₂Cl₂ to HCl. The length L of the hollow portion ranged from 0 μm (no hollow portion) to 42 μm. At various lengths L, the crystal defect density inside the n-type silicon layer 12 (see FIG. 1) and the p-type silicon pillar 14 (see FIG. 1) was measured.

As seen from FIG. 2, with respect to the length L of the hollow portion, the crystal defect density inside the SJ structure is sharply suppressed when the length L of the hollow portion is 5 μm or less or 15 μm or more. Hence, by adjusting the length L of the hollow portion to such length, crystal defects inside the SJ structure can be suppressed so that the presence of such hollow portions does not affect the characteristics (including reliability such as leak voltage) of the semiconductor device, such as the vertical MOSFET.

### Second Embodiment

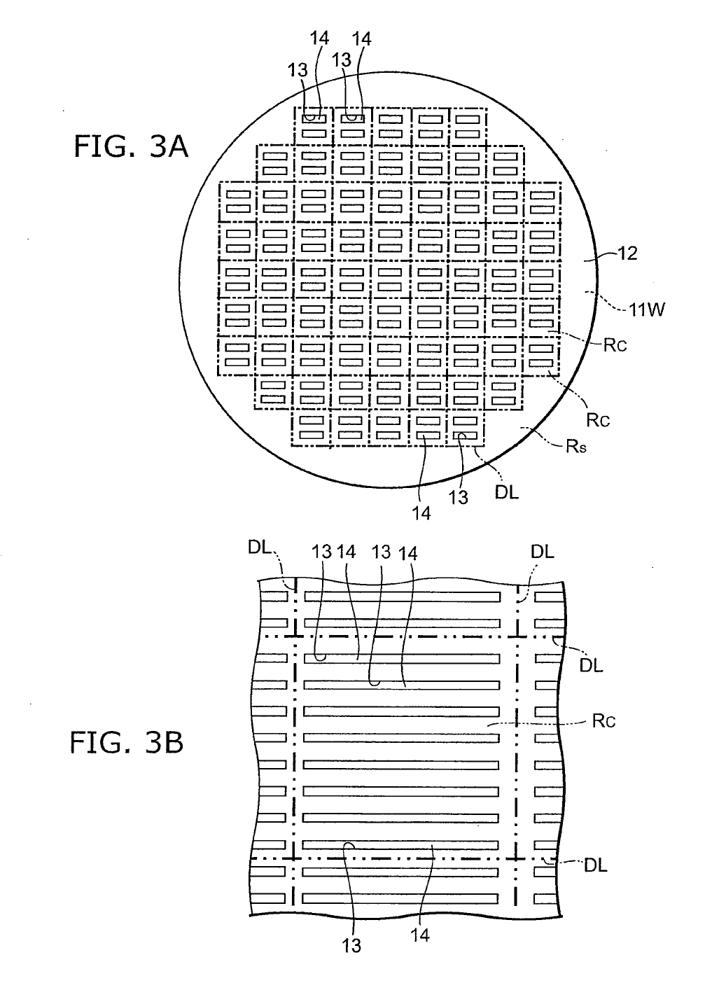

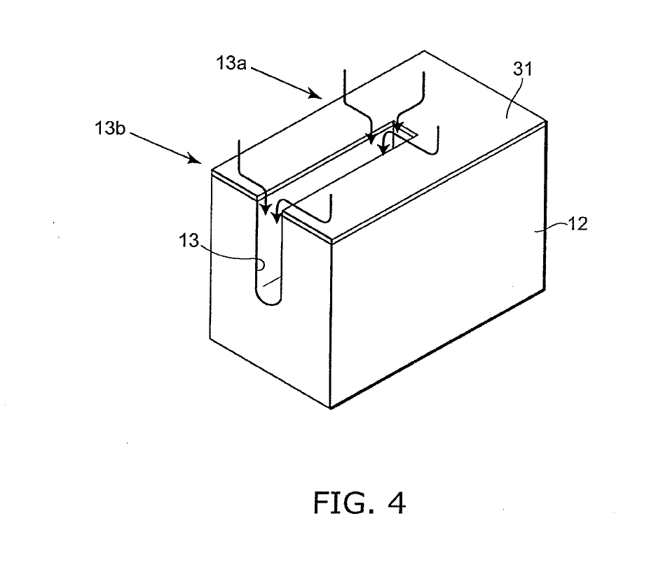

Next, a method for manufacturing a semiconductor device according to a second embodiment is described. FIGS. 3A and 3B are plan views illustrating the method for manufacturing a semiconductor device according to this embodiment, where FIG. 3A is a plan view of an entire wafer, and FIG. 3B is a partially enlarged plan view illustrating one chip region shown in FIG. 3A. In the figures, for convenience of illustration, the area of the chip region and the width of the p-type silicon pillar relative to the wafer are depicted with larger size than in reality. FIG. 4 illustrates the flow of raw material gas during epitaxial growth of p-type silicon in the trench.

First, as shown in FIG. 3A, a wafer 11W made of n⁺-type single crystal silicon is prepared. Then, n-type silicon is epitaxially grown on the upper surface of the wafer 11W to form an n-type silicon layer 12.

Next, a plurality of trenches 13 extending in one direction (pillar direction) parallel to the upper surface of the n-type silicon layer 12 are formed from the upper surface side of the n-type silicon layer 12 halfway through the n-type silicon layer 12. As shown in FIGS. 3A and 3B, the trench 13 is formed discontinuously for each chip region Rc.

Next, p-type silicon as a semiconductor material is epitaxially grown and deposited in the trench 13 to bury a p-type silicon pillar 14 in the trench 13. Here, the epitaxial growth is performed by e.g. the CVD (chemical vapor deposition) method after the upper surface of the n-type silicon layer 12 is covered with a silicon oxide film 31 (see FIG. 4). This CVD is performed under the condition that, for instance, dichlorosilane (DCS, SiH₂Cl₂) and hydrochloric acid (HCl) are used as raw material with a temperature of 950-1100° C. and under a reduced pressure of 1−40 kPa. The raw material can be trichlorosilane (TCS), DCS, SiH₄, or a mixed gas of any of these gases with as hydrochloric acid (HCl) or chlorine (Cl₂) having an etching effect.

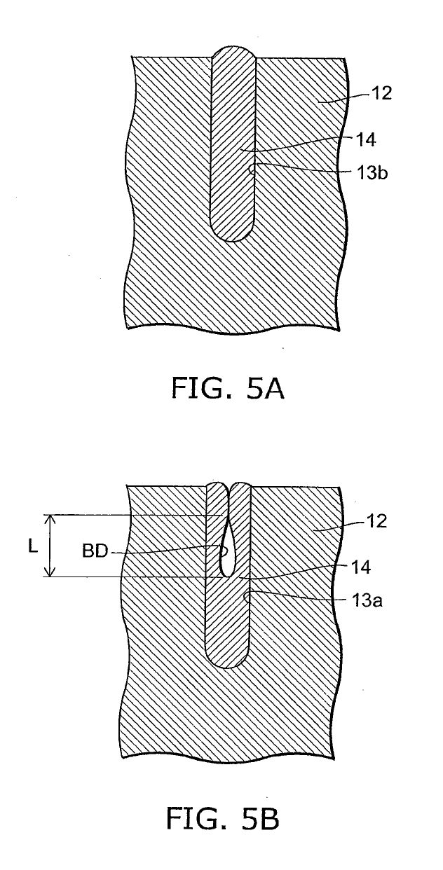

When the p-type silicon pillar 14 is thus buried in the trench 13, a hollow portion BD is formed. Here, formation of the hollow portion BD is described. FIG. 4 illustrates the flow of raw material gas during epitaxial growth of p-type silicon in the trench. FIGS. 5A and 5B are sectional views illustrating a hollow portion formed in the p-type silicon buried in the trench, where FIG. 5A shows a shape for complete filling, and FIG. 5B shows a shape with void formation.

As shown in FIG. 4, when silicon is epitaxially grown in the trench 13, the raw material gas is caused to penetrate into the trench 13 after the upper surface of the n-type silicon layer 12 is covered with a silicon oxide film 31. Here, in the portion (hereinafter referred to as “intermediate portion 13b”) of the trench 13 except both end portions 13a in the longitudinal direction (pillar direction), the raw material gas is supplied from two directions, i.e., in the width direction (SJ direction) of the trench 13. In contrast, in the end portion 13a of the trench 13, the raw material gas is supplied from three directions. That is, in the end portion 13a, the raw material gas is supplied not only from the two directions in the width direction (SJ direction) of the trench 13, but also from one direction on the terminating side of the trench in the longitudinal direction (pillar direction). Hence, the supply amount of the raw material gas is larger in the end portion 13a of the trench 13 than in the intermediate portion 13b. Furthermore, the end portion 13a is different from the intermediate portion 13b in the crystal orientation of the inner surface of the trench 13. These factors make growth of silicon generally faster in the end portion 13a of the trench 13 than in the intermediate portion 13b.

Consequently, even if CVD is performed under the condition that the inside of the trench 13 is completely filled with silicon in the intermediate portion 13b of the trench 13 as shown in FIG. 5A, in both end portions 13a of the trench 13, growth of silicon at the opening of the trench 13 is faster as shown in FIG. 5B. Thus, in both end portions 13a of the trench 13, the opening is occluded before the inside is filled with silicon, and a hollow portion BD is more likely to occur. That is, in both end portions 13a, the opening is occluded earlier than the inside of the trench 13, and a hollow portion BD is formed.

Furthermore, depending on the growth condition, a void as shown in FIG. 5B may be formed also in the trench intermediate portion. In this case, in the trench intermediate portion, the opening is occluded earlier than the inside of the trench 13, and a hollow portion BD is formed. Conventionally, voids are allowed because voids do not directly affect the breakdown voltage and on-resistance. Alternatively, in order to avoid the occurrence of hollow portions BD, the conventional technique selects a condition for significantly slow growth rate so that the inside of the trench 13 is completely filled. In this embodiment, even if a hollow portion BD is formed, by adjusting the length L of the hollow portion BD along the trench direction, crystal defects of silicon in the trench 13 affecting the reliability are suppressed. That is, by setting the length L of the hollow portion BD to 5 μm or less or 15 μm or more, the occurrence of crystal defects of silicon in the trench 13 can be suppressed (see FIG. 2). Thus, even if a hollow portion BD occurs, a semiconductor device with high reliability can be produced by controlling the length of the hollow portion BD.

Next, a p-type base region 15, a source region 16, and a contact region 17 shown in FIG. 1 are formed by conventional methods. Furthermore, a diffusion region 20 is formed along the dicing line DL shown in FIGS. 3A and 3B. Then, a gate electrode 21 and a gate insulating film 22 shown in FIG. 1 are formed on the n-type silicon layer 12. A source electrode 23 is formed so as to cover the gate electrode 21 and the gate insulating film 22. On the other hand, a drain electrode 24 shown in FIG. 1 is formed on the lower surface of the wafer 11W shown in FIGS. 3A and 3B.

Next, as shown in FIGS. 3A and 3B, the wafer 11W and the configuration formed thereon are diced along the dicing line DL and divided into a plurality of chips. The divided chip is housed in a prescribed package. Thus, a semiconductor device is completed.

The invention has been described above with reference to the embodiments. However, the invention is not limited to these embodiments. For instance, those skilled in the art can suitably modify the above embodiment by addition, deletion, or design change of components, or by addition, omission, or condition change of process steps. Such modifications are also encompassed within the scope of the invention as long as they fall within the spirit of the invention.

For instance, in the above description of the embodiments, the first conductivity type is n-type, and the second conductivity type is p-type. However, the invention can be practiced also in the case where the first conductivity type is p-type and the second conductivity type is n-type. Furthermore, an n⁻-type buffer layer having lower impurity concentration than the n-type silicon layer 12 may be provided between the n⁺-type silicon substrate 11 and the n-type silicon layer 12. In the above description of the embodiments, a semiconductor chip having a planar MOS gate structure is taken as an example. However, the semiconductor chip according to the invention can be practiced also in a trench MOS gate structure (UMOS structure). In the above description of the embodiments, silicon (Si) is taken as an example of semiconductor. However, the semiconductor can be e.g. a compound semiconductor such as silicon carbide (SiC) or gallium nitride (GaN), or a wide bandgap semiconductor such as diamond.

The pillar planar pattern of the super junction structure is not limited to the above example. Besides the striped pattern, the embodiments can be practiced in various patterns such as a mesh or offset mesh pattern.

In the above embodiments, only the structure of the cell section is described. However, the terminal structure of the device is not particularly limited. The embodiments can be practiced in various structures such as a guard ring structure, a field plate structure, or a RESURF structure.

In the example of the above embodiments, the semiconductor device is a MOSFET having a super junction structure. However, the invention is not limited thereto. The semiconductor device may be, for instance, a hybrid device of MOSFET and SBD (Schottky barrier diode), or an IGBT (insulated gate bipolar transistor).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

1. A semiconductor device comprising:
a first semiconductor layer of a first conductivity type with a trench formed; and
a second semiconductor layer of a second conductivity type buried in the trench and including a hollow portion,
length of the hollow portion along depth direction of the trench being 5 μm or less or 15 μm or more.

2. The device according to claim 1, wherein the hollow portion is provided in both end portions in longitudinal direction of the trench.

3. The device according to claim 1, wherein the hollow portion is provided in an intermediate portion other than both end portions in longitudinal direction of the trench.

4. The device according to claim 1, wherein a portion of the first semiconductor layer and the second semiconductor layer are alternately provided to form a super junction structure.

5. A semiconductor device comprising:
a first main electrode;
a second main electrode;
a first semiconductor layer of a first conductivity type provided between the first main electrode and the second main electrode and having a first trench and a second trench, the second trench aligned with the first trench formed at a predetermined pitch in a direction perpendicular to a direction from the first main electrode toward the second main electrode;
a first buried semiconductor layer of a second conductivity type buried in the first trench and including a hollow portion in the first buried semiconductor layer;
a second buried semiconductor layer of the second conductivity type buried in the second trench and including a hollow portion in the second buried semiconductor layer;
a third semiconductor layer of the second conductivity type provided between the first buried semiconductor layer and the second main electrode;
a fourth semiconductor layer of the first conductivity type selectively provided between a portion of the third semiconductor layer and the second main electrode;
a fifth semiconductor layer of the second conductivity type provided between the second buried semiconductor layer and the second main electrode;
a sixth semiconductor layer of the first conductivity type selectively provided between a portion of the fifth semiconductor layer and the second main electrode; and
a control electrode provided between a portion between the first buried semiconductor layer and the second buried semiconductor layer and the second main electrode via an insulating film,
the first main electrode being electrically connected to the first semiconductor layer,
the second main electrode being connected to the fourth semiconductor layer and the sixth semiconductor layer,
a length of the hollow portion along depth direction of the first and second trenches being 5 μm or less or 15 μm or more.

6. The device according to claim 5, wherein a portion of the first semiconductor layer is provided between the first buried semiconductor layer and the second buried semiconductor layer to form a super junction structure.

7. A method for manufacturing a semiconductor device, comprising:
forming a trench in a first semiconductor layer of a first conductivity type; and
forming a second semiconductor layer by supplying a raw material gas to both end portions in longitudinal direction of the trench along one direction along the longitudinal direction and along two directions along width direction of the trench and supplying the raw material gas to an intermediate portion of the trench other than both the end portions along the two directions along the width direction to grow a semiconductor material of a second conductivity type in the trench, the second semiconductor layer including a hollow portion inside the semiconductor material of the second conductivity type,
length of the hollow portion along depth direction of the trench being set to 5 μm or less or 15 μm or more.

8. The method according to claim 7, wherein in the forming a second semiconductor layer, in both the end portions, opening of the trench is occluded with the semiconductor material earlier than inside of the trench to form the hollow portion.

9. The method according to claim 7, wherein in the forming a second semiconductor layer, in the intermediate portion, opening of the trench is occluded with the semiconductor material earlier than inside of the trench to form the hollow portion.

10. The method according to claim 7, wherein in the forming a second semiconductor layer, ratio of SiH₂Cl₂ to HCl is changed to adjust the length of the hollow portion.
